(19) United States
(12) Patent Application Publication
(10) Pub. No.: US 2019/0238981 A1
(43) Pub. Date: Aug. 1, 2019

(54) SYSTEM AND METHOD FOR PRIORITIZING AUDIO SIGNALS TO A SPEAKER

(71) Applicant: Purkey's Fleet Electric, Inc., Lowell, AR (US)

(72) Inventors: Joshua Harris, Manti, UT (US); Dale Henningson, Manti, UT (US)

(73) Assignee: Purkey's Fleet Electric, Inc., Lowell, AR (US)

(21) Appl. No.: 16/259,714

(22) Filed: Jan. 28, 2019

Related U.S. Application Data
(60) Provisional application No. 62/622,788, filed on Jan. 26, 2018.

(51) Int. Cl. H04R 3/12; H04R 1/40; H03K 19/20

(52) U.S. Cl. CPC H04R 3/12; H04R 2420/07; H03K 19/20; H04R 1/403

(57) ABSTRACT

A system and method for prioritizing audio signals for transmission to a speaker. The system includes an audio interrupter configured to receive one or more audio signals for transmission to one or more speakers. Based upon pre-configured logic, the audio interrupter prioritizes audio signals, routing the prioritized signal to the speakers.

### CROSS-REFERENCE TO RELATED APPLICATIONS

This application claims the benefit of U.S. Provisional Application Ser. No. 62/622,788, filed on Jan. 26, 2018, which is incorporated herein by reference.

### TECHNICAL FIELD

The present disclosure relates to audio speaker systems, network interconnectivity (e.g., M2M, IoT), and audio signal processing. More particularly, the present disclosure relates to a system and method for prioritizing audio signals for transmission to an electromechanical transducer.

### BACKGROUND

As more and more vehicle operators adapt to emerging and even mainstream technologies like smartphones and tablets, they see increasing possibilities to utilize these technologies in the vehicles they are operating. Much of the user interaction with these technologies involves auditory, visual, and tactile feedback, but are reasonably limited (and in some cases legally limited) to auditory feedback while driving. The speakers in these technologies, if available, are typically very small and have very limited volume range. When operating the vehicle, the engine, road, and radio noise make it very difficult to hear the auditory output.

Vehicle media systems already offer auxiliary audio inputs, which may include wireless connectivity (e.g., Bluetooth®), USB, and other inputs. Generally, these alternate audio sources must be selected manually through the vehicle's infotainment system and have no user-defined prioritization and configuration ability. Often, the modern technologies only broadcast intermediate audio messages such as navigation commands or message alerts, and the operator must choose between hearing those intermediate notifications or listening to another audio source (e.g., radio, CD) and not hearing the notifications. If the driver wants to listen to the radio, there is a high probability that the audio for the smartphone, tablet or other technology will not be heard by the operator. In addition, other systems are often added to the vehicle, such as lane departure warnings or collision warning systems, which have their own audio systems that overlap with OEM audio systems. Again, if the radio is playing, these audio signals compete with the radio and may not be heard well, or at all, by the operator.

While some sound systems with wireless connectivity can interrupt audio streams for hands-free calling, they do not pause for other audio messages from smartphones, tablets, or other sources.

Further, for the above-mentioned vehicle sound systems, the sound systems (e.g., infotainment unit) must be powered on to play any audio from any source.

Accordingly, there is a need for a system and method of playing audio through the vehicle's speakers 1) when the vehicle's sound system is turned off; 2) that is capable of interrupting the audio from the vehicle's sound system, 3) that is customizable to the user to play audio from any connected source, and 4) in the case when there are multiple audio signals, prioritizing and playing the highest priority signal. The present invention solves these, and other, problems.

### SUMMARY OF EXAMPLE EMBODIMENTS

In one embodiment, an audio interrupter is configured to receive one or more audio signals and comprises control circuitry for detecting and prioritizing audio sources, an audio switch, and one or more audio outputs.

In one embodiment, a method for prioritizing audio signals for transmission to an electromechanical transducer (e.g., speaker) comprises an audio interrupter coupled to a vehicle battery, the audio interrupter configured to receive one or more audio signals for transmission to one or more speakers; based upon preconfigured logic, the audio interrupter prioritizes audio signals and, via an audio switch, transmits the prioritized signal to the speakers.

### BRIEF DESCRIPTION OF THE DRAWINGS

FIG. 1 is a block diagram of a system for prioritizing audio signals for transmission to a speaker using an audio interrupter;

FIG. 2 is a perspective view of an audio interrupter; and

FIG. 3 is a flow chart using an audio interrupter in a vehicle.

### DETAILED DESCRIPTION OF EXAMPLE EMBODIMENTS

The following descriptions depict only example embodiments and are not to be considered limiting in scope. Any reference herein to “the invention” is not intended to restrict or limit the invention to exact features or steps of any one or more of the exemplary embodiments disclosed in the present specification. References to “one embodiment,” “an embodiment,” “various embodiments,” and the like, may indicate that the embodiment(s) so described may include a particular feature, structure, or characteristic, but not every embodiment necessarily includes the particular feature, structure, or characteristic. Further, repeated use of the phrase “in one embodiment,” or “in an embodiment,” do not necessarily refer to the same embodiment, although they may.

Reference to the drawings is done throughout the disclosure using various numbers. The numbers used are for the convenience of the drafter only and the absence of numbers in an apparent sequence should not be considered limiting and does not imply that additional parts of that particular embodiment exist. Numbering patterns from one embodiment to the other need not imply that each embodiment has similar parts, although it may.

Accordingly, the particular arrangements disclosed are meant to be illustrative only and not limiting as to the scope of the invention, which is to be given the full breadth of the appended claims and any and all equivalents thereof. Although specific terms are employed herein, they are used in a generic and descriptive sense only and not for purposes of limitation. Unless otherwise expressly defined herein, such terms are intended to be given their broad, ordinary, and customary meaning not inconsistent with that applicable in the relevant industry and without restriction to any specific embodiment hereinafter described. As used herein, the article “a” is intended to include one or more items. When used herein to join a list of items, the term “or” denotes at least one of the items, but does not exclude a plurality of items of the list. For exemplary methods or processes, the sequence and/or arrangement of steps described herein are illustrative and not restrictive.

It should be understood that the steps of any such processes or methods are not limited to being carried out in any particular sequence, arrangement, or with any particular graphics or interface. Indeed, the steps of the disclosed processes or methods generally may be carried out in various sequences and arrangements while still falling within the scope of the present invention.

The term “coupled” may mean that two or more elements are in direct physical contact. However, “coupled” may also mean that two or more elements are not in direct contact with each other, yet still cooperate or interact with each other.

The terms “comprising,” “including,” “having,” and the like, as used with respect to embodiments, are synonymous, and are generally intended as “open” terms (e.g., the term “including” should be interpreted as “including, but not limited to,” the term “having” should be interpreted as “having at least,” the term “includes” should be interpreted as “includes, but is not limited to,” etc.).

As previously discussed, there is a need for a system and method of playing audio through the vehicle's speakers even when the vehicle's sound system is turned off, interrupting the audio from the vehicle's sound system when it is on to play audio from smartphone or tablet devices, and, in the case when there are multiple audio signals, prioritizing and playing the highest priority signal. The audio prioritizer apparatus and method disclosed herein solve these problems and others.

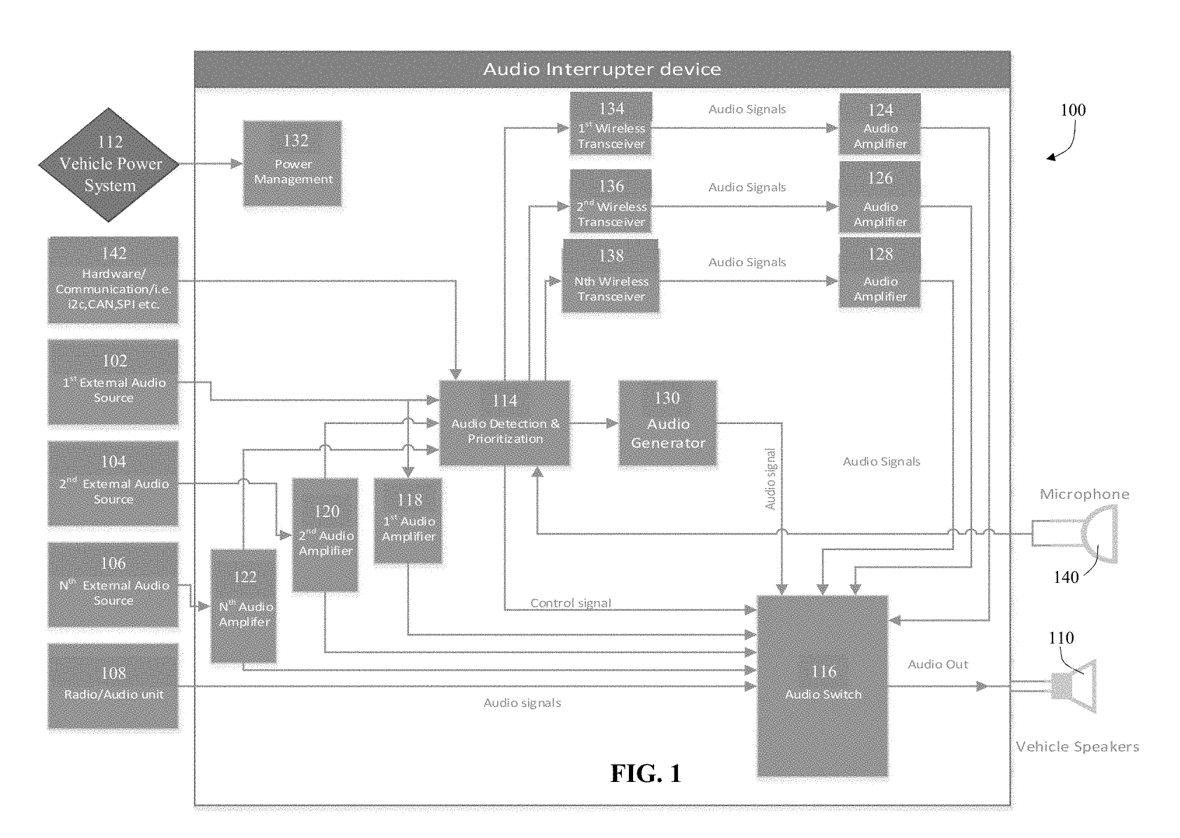

FIG. 1 illustrates a block diagram of an audio interrupter apparatus 100 (also referred to herein as an “audio prioritizer”). As shown, the audio interrupter 100 is interposed between one or more external audio sources 102, 104, 106, 108 and one or more speakers 110, and is coupled to a vehicle power system 112. In one embodiment, the audio interrupter 100 is coupled to the ignition of the vehicle, so as to not drain the vehicle's battery when the vehicle is not running. The external audio sources 102, 104, 106, 108 are received by the audio detection and prioritization component 114. In one non-limiting example, the audio detection and prioritization component 114 comprises a microcontroller (or other processor and memory) to measure filtered analog-to-digital converter (ADC) signals to determine when audio signals are present, with digital outputs to control the audio switch 116 (“control signals”). Using logic on the microcontroller of the audio detection and prioritization component 114, received audio signals from external audio sources 102, 104, 106, 108 are prioritized and transmitted accordingly. For example, in one embodiment, prioritized signals are sent from the audio detection and prioritization component 114 to corresponding audio amplifiers 118, 120, 122, 124, 126, 128 to drive the vehicle speaker(s) 110. While multiple audio amplifiers 118, 120, 122, 124, 126, 128 are illustrated, it will be appreciated that a single amplifier may be used in a system that comprises two audio switches 116. The audio switch 116 may comprise one or more double-pole relays to switch the audio signals with the control signals from the audio detection and prioritization component 114, which turns the corresponding relays On/Off by applying the control signals to the coils of the relays. It will be appreciated that the audio switch 116 may be in either a post-amplifier or pre-amplifier configuration.

In one embodiment, an audio generator 130 is configured to transmit pre-defined signals, such as warnings, notifications, informational alerts, or other signals. Accordingly, the audio detection and prioritization components 114 may be configured to prioritize cell phone notifications above a radio signal. Therefore, if a user is listening to the radio when his/her cellphone receives a notification, the radio signal is interrupted, using the audio detection and prioritization components 114 and the audio switch 116, and the cellphone signal is transmitted to the speaker 110.

In one embodiment, the audio interrupter 100 comprises power management 132 which comprises circuitry to produce a regulated power supply. Power management 132 may be coupled to the ignition of the vehicle, allowing the audio interrupter to only function when the ignition is in the On position. Further, because the audio interrupter is not reliant on the power status of the vehicle radio/infotainment system (or other vehicle audio system), the audio interrupter 100 is capable of sending audio signals to the speakers 110 independent of the power status of the radio/infotainment system of the vehicle. For example, if a user chose to have the vehicle radio or infotainment system powered off, the audio interrupter 100 would still transmit prioritized audio to the speakers. Wireless transceivers 134, 136, 138 may be included for wireless audio transmission and communication. Further, the audio interrupter 100 may comprise one or more electromechanical transducers (e.g., microphone 140) for speech input and/or noise reduction. In one embodiment, the audio interrupter 100 may be coupled to external communications 142 (e.g., SAE J1939, LIN networks, etc.) for receiving/broadcasting commands, information, and status.

In one embodiment, a method for prioritizing audio signals for transmission to a speaker comprises an audio interrupter 100 coupled to a vehicle power system 112 (e.g., vehicle battery), the audio interrupter 100 configured to receive two audio signals from an external audio source 102, 104 (either wired or wireless signals external to the audio interrupter) for transmission to one or more speakers 110; based upon preconfigured logic in a microcontroller, the audio interrupter 100 prioritizes audio signals and controls an audio switch 116 accordingly, the audio switch 116 transmitting the prioritized signal to the speakers 110. Accordingly, a user is able to easily receive important notifications even when not listening to that particular audio input. For example, a user may hear a notification from a cellphone despite listening to a CD on the vehicle infotainment system. Further, the audio interrupter 100 is capable of sending a signal to the speakers 110 even when the vehicle audio system is powered off. For example, the audio interrupter 100 is coupled to the vehicle power system 112 directly via the ignition switch, and therefore is not controlled by the power status of the vehicle audio system. Accordingly, if an audio signal is received by the audio interrupter 100 that has high priority, that audio signal is transmitted to the speakers 110 regardless of the status of the vehicle audio system. Another example of use would be for a lane departure notification to be transmitted and played through the speakers 110, regardless of the power status of the vehicle audio system or what audio source is currently broadcasting audio via the vehicle audio system.

In one embodiment, the audio interrupter may comprise a dual-source, single-output audio switch, wherein one wireless audio source is at line level and the other audio source is at speaker level; the output being at least one stereo speaker at speaker level. Utilizing a pre-switch amplifier on the wireless audio source and an un-conditioned audio connection from the speaker level source, the output to a 4-8 ohm stereo speaker can be seamlessly switched via a microcontroller whenever the customer-defined scenario of wireless audio transmission is sensed (via the microcontroller measuring ADC signals).

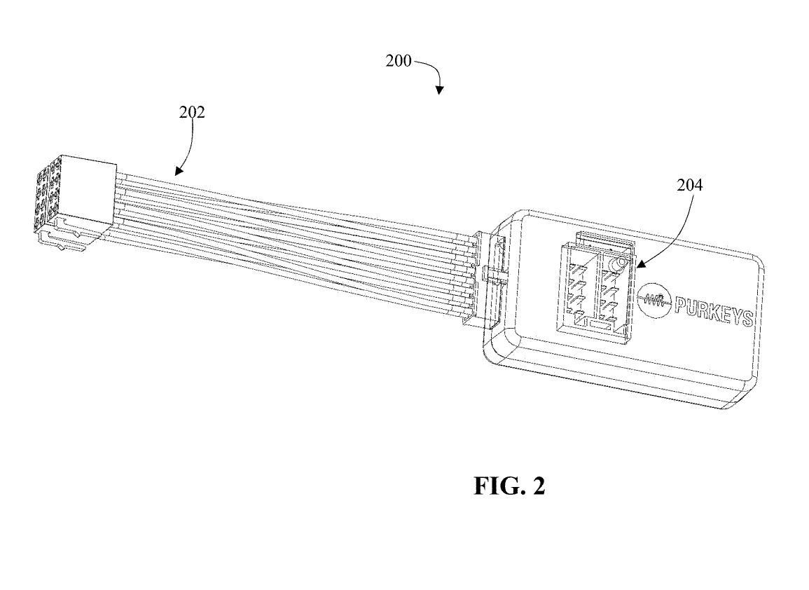

In one embodiment, as shown in FIG. 2, the audio interrupter 200 may have a small form factor that allows for easy fitment behind radios internal to a vehicle's infotainment system. As shown, the audio interrupter 200 comprises one or more inputs 202 and one or more outputs 204.

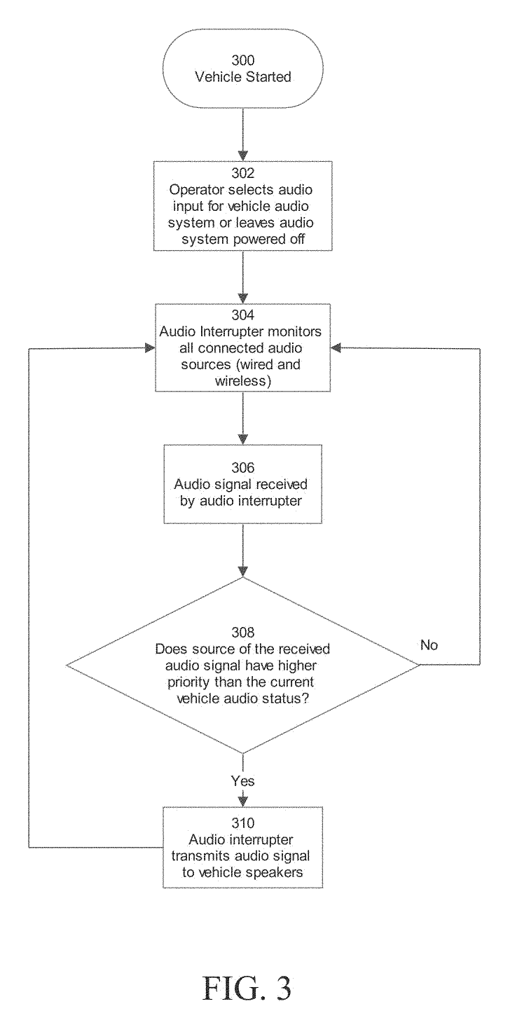

In one embodiment, as shown in FIG. 3, a system and method of using an audio interrupter is illustrated. In step 300, the vehicle is started. In step 302, the operator of the vehicle may select an audio source for transmitting through the vehicle speakers or may leave the vehicle audio system powered off. Regardless of step 302, the audio interrupter monitors all connected audio sources in 304. These external audio sources may be an operator's smartphone, GPS unit, vehicle radio, vehicle component (e.g., SAE J1939, LIN networks), or other audio source. In step 306, the audio interrupter receives a signal from one of these external audio sources. In step 308, the audio interrupter determines whether the received audio signal has a higher priority than the current audio signal, if any. For example, if no audio is currently being transmitted to the speakers, then the received audio will be transmitted in step 310. If an audio signal is currently being transmitted to the speakers, the audio interrupter will determine, using programmed logic, if the received audio signal is higher in priority than the current playing audio. For example, if the current audio is the FM radio, and the audio interrupter receives a signal (e.g., alert) from the operator's cell phone, the audio interrupter may switch the audio source from the FM radio to the cell phone so that the operator hears the cell phone alert. If the audio signal is not higher in priority, then step 304 is repeated.

The priority configuration of audio signals may be pre-defined by the manufacturer or may be programmed by a user. In one non-limiting example, a user may connect to the audio interrupter wirelessly (e.g., Bluetooth) to configure audio priorities using a user interface (e.g., smartphone application). The user may then select and prioritize the audio sources accordingly. For example, a user may determine that vehicle notifications (e.g., lane departure, tire pressure, etc.) have the highest priority, that cell phone notifications are secondary to the vehicle notifications, and so on. Accordingly, the audio detection and prioritization component can then route the signals based upon the user-defined priorities. In step 310, upon commencing transmission of the current highest priority audio signal, step 304 is repeated with the audio interrupter monitoring audio signals. It will be appreciated that a plurality of configurations are available. Further, the audio interrupter may also receive and stream audio from wireless connections (e.g., Bluetooth).

As appreciated from the foregoing disclosure, the audio interrupter disclosed herein solves the need for a system and method of playing audio through the vehicle's speakers even when the vehicle's sound system is turned off, interrupting the audio from the vehicle's sound system when it is on to play audio from smart phone or tablet devices, and, in the case when there are multiple audio signals, prioritizing and playing the highest priority signal.

Exemplary embodiments are described above. No element, act, or instruction used in this description should be construed as important, necessary, critical, or essential unless explicitly described as such. Although only a few of the exemplary embodiments have been described in detail herein, those skilled in the art will readily appreciate that many modifications are possible in these exemplary embodiments without materially departing from the novel teachings and advantages herein. Accordingly, all such modifications are intended to be included within the scope of this invention.

What is claimed is:

1. An audio interrupter for prioritizing and transmitting received audio signals, the audio interrupter, comprising:
a power input;
at least one audio input;
an audio detection and prioritization component;
an audio switch; and
at least one audio output.

2. The audio interrupter of claim 1, further comprising at least one audio amplifier.

3. The audio interrupter of claim 1, further comprising at least one wireless transceiver.

4. The audio interrupter of claim 1, wherein the audio detection and prioritization component comprises a microcontroller or microprocessor.

5. The audio interrupter of claim 1, wherein the audio detection and prioritization component comprises programmed logic to determine priority.

6. The audio interrupter of claim 1, further comprising an electromechanical transducer for receiving audio.

7. A system for prioritizing vehicle audio using an audio interrupter, the system comprising:
at least two audio sources;
at least one speaker for audio output; and
an audio interrupter interposed between the audio sources and the speaker;
wherein the audio interrupter receives and, using programmed logic, transmits audio signals to the speakers based upon audio source priority.

8. The system of claim 7, wherein the audio interrupter is coupled to an ignition switch of a vehicle.

9. The system of claim 8, wherein the audio interrupter transmits audio signals to the speakers when the vehicle audio system is powered off.
